(19) United States
(12) Patent Application Publication
(10) Pub. No.: US 2013/0061908 A1
(43) Pub. Date: Mar. 14, 2013

(54) ANGLE ADJUSTMENT CONTROLLER AND METHOD FOR PHOTOVOLTAIC CELLS

(71) Applicant: Robert Gregory Wagoner, Roanoke, VA (US)

(72) Inventor: Robert Gregory Wagoner, Roanoke, VA (US)

(21) Appl. No.: 13/231,113

(22) Filed: Sep. 13, 2011

(51) Int. Cl. H01L 31/052

(52) U.S. Cl. 136/246

(57) ABSTRACT

A photovoltaic power system includes one or more photovoltaic cells that supplies an output power, a controller that controls an angle of the one or more photovoltaic cells with respect to an incident light, and a power converter that converts the output power of the photovoltaic cells to converted output power, wherein the power converter has a threshold input power. The controller is configured to control the angle of the one or more photovoltaic cells with respect to the incident light such that a total output power of the photovoltaic cells is at or below the threshold input power of the power converter.

### BACKGROUND OF THE INVENTION

The field of the present disclosure relates generally to power generation using photovoltaic cells. More particularly, the present disclosure relates to adjusting an angle of photovoltaic cells to adjust power output.

A general term for devices that convert light to electrical energy is “photovoltaic cells.” Sunlight is a subset of light, and solar cells are a subset of photovoltaic cells. In order to obtain a higher current and voltage, photovoltaic cells are electrically connected to form a photovoltaic module or array. The instantaneous output power of the photovoltaic arrays is dependent upon many factors, such as irradiance (i.e., an amount of light striking the photovoltaic array), temperature, cleanliness of the photovoltaic array, humidity and other environmental factors. Photovoltaic arrays generate maximum power when the array is positioned perpendicular to the incident light. If the photovoltaic array is not positioned perpendicular to the incident light, the photovoltaic array will generate less than maximum power.

Photovoltaic arrays may be fixedly mounted (i.e., non-adjustable), or adjustably mounted such that an angle of the photovoltaic array is adjustable with respect to the incident light. In photovoltaic systems having a fixedly mounted array, the array is mounted at an angle to maximize the average power output of the photovoltaic array (i.e., by positioning the photovoltaic array at 90 degrees to the incident light). Typically, in photovoltaic systems having an adjustable angle, the angle of the photovoltaic array is set to continuously maintain a 90 degree angle to the incident light, thereby allowing maximum power output of the photovoltaic array.

However, due to many factors, such as cloud cover, temperature, cleanliness of the photovoltaic array, humidity and other environmental factors, the photovoltaic array may produce less power than the photovoltaic array is capable of producing in ideal conditions. For example, under cloudy conditions, the photovoltaic array may produce less power than on a sunny day with no cloud cover due to a reduction in total irradiance. Typically the photovoltaic array is oversized to compensate for such reductions in output power. Thus, in ideal conditions, the oversized photovoltaic array may be capable of producing excess output power.

Typically, the photovoltaic array is oversized as compared to the converter of the photovoltaic system (i.e., the photovoltaic array has a maximum power output that exceeds the maximum input power rating of a converter). In such instances, a converter must be designed to work at higher power levels (e.g., higher voltage and/or current levels) than necessary to produce a desired output power. However, this results in the need for an oversized converter, having an undesirable increase in cost and reduction in reliability.

### BRIEF DESCRIPTION OF THE INVENTION

In one aspect, a photovoltaic power system comprises one or more photovoltaic cells that supplies an output power, a controller that controls an angle of the one or more photovoltaic cells with respect to an incident light, and a power converter that converts the output power of the photovoltaic cells to converted output power, the power converter having a threshold input power. The controller is configured to control the angle of the one or more photovoltaic cells with respect to the incident light such that a total output power of the photovoltaic cells is at or below the threshold input power of the power converter.

In another aspect, a method of adjusting the power output of a photovoltaic power system comprises determining an output power of one or more photovoltaic (PV) cells of the system, and controlling an angle of the one or more photovoltaic cells with respect to an incident light such that a total output power of the photovoltaic cells is at or below a threshold input power of a power converter of the system.

In another aspect, a computer readable storage medium storing a non-transitory computer program for a method of adjusting the power output of a photovoltaic power system comprises determining an output power of one or more photovoltaic (PV) cells of the system and controlling an angle of the one or more photovoltaic cells with respect to an incident light such that a total output power of the photovoltaic cells is at or below a threshold input power of a power converter of the system.

### BRIEF DESCRIPTION OF THE DRAWINGS

FIG. 1 is a block diagram of an exemplary embodiment of a photovoltaic power system according to the present disclosure.

FIG. 2 is an example voltage-current and power-current curve for a photovoltaic array.

FIG. 3 is an example plot of a typical photovoltaic array voltage-current (V-I) curve and a typical photovoltaic array power curve at a particular temperature and irradiance

FIG. 4 is an example of a photovoltaic array disposed at a second angle to an incident light beam.

### DETAILED DESCRIPTION OF THE INVENTION

The systems and methods described herein facilitate adjusting an angle of one or more photovoltaic cells to adjust power output. In embodiments, the angle of the photovoltaic cells is adjusted with respect to the incident light to facilitate a reduction in power output below a threshold power input level of a power converter. For example, the technical effect of the systems and methods described herein facilitate reducing the power output of one or more photovoltaic cells by adjusting the angle of the photovoltaic cells such that one or more photovoltaic cells are not operating at a maximum power output level.

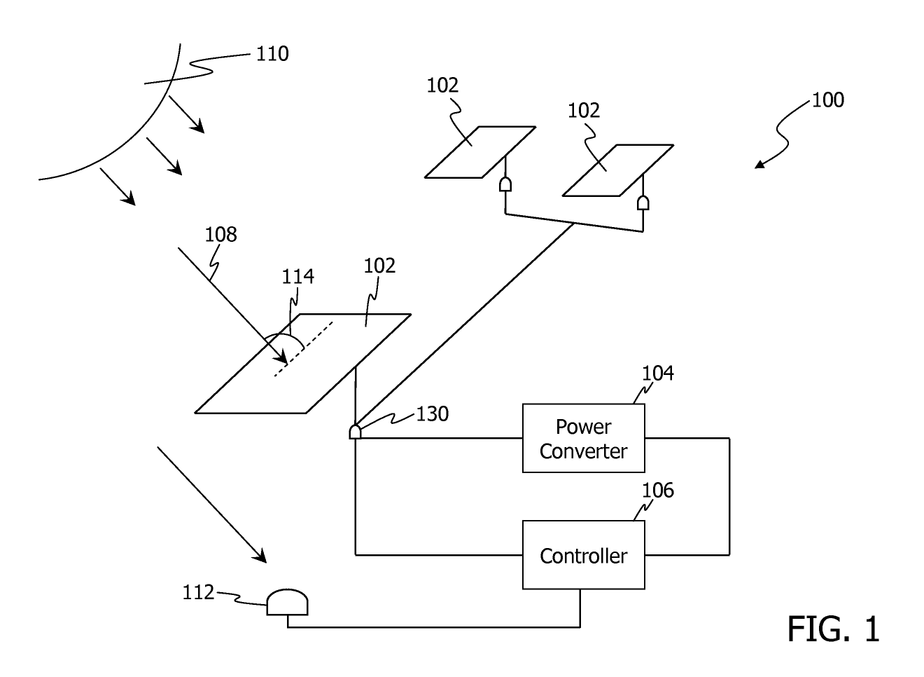

Shown in FIG. 1 is an exemplary embodiment of a photovoltaic power generation system 100. In the exemplary embodiment, the photovoltaic power generation system 100 includes a photovoltaic cell 102, a power converter 104 and a controller 106. In one embodiment, photovoltaic power generation system 100 is connected to an electrical grid (not shown) comprising an electrical distribution grid, an electrical transmission grid, or any type of electrical grid configured for delivering electricity.

Photovoltaic cell 102 receives incident light 108 from a light source 110. In one embodiment, photovoltaic cell 102 is a solar cell, in which case incident light 108 is solar energy. In another embodiment, a plurality of photovoltaic cells 102 are electrically connected to form a photovoltaic cell array, for example, to increase the total power output capability of photovoltaic power generation system 100.

Incident light 108 strikes photovoltaic cell 102 at an incident angle 114. In one embodiment, a tracking device 112, for example a solar tracking device, is used to determine incident angle 114. In another embodiment, tracking device 112 is integral with photovoltaic cell 102 or other components of photovoltaic power generating system 100. Alternatively, tracking device 112 is a separate component.

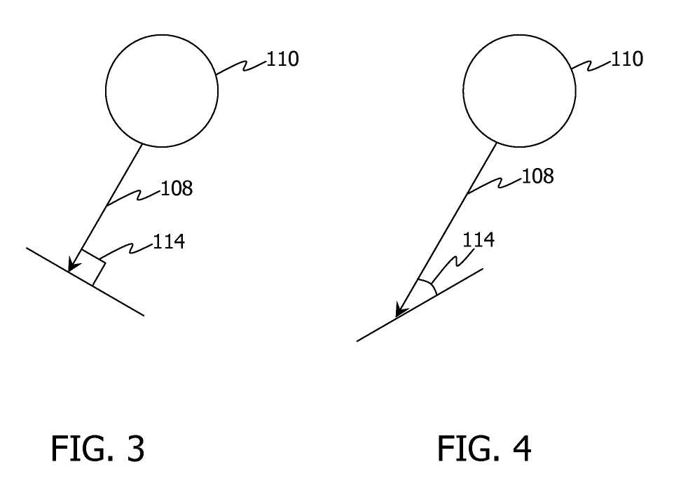

Upon receiving incident light 108, photovoltaic cell 102 generates a DC output power. The DC output power generated by photovoltaic cell 102, or array of photovoltaic cells 102, is dependent upon incident angle 114. For example, as shown in FIG. 3, when incident angle 114 is perpendicular (i.e., 90 degrees) to photovoltaic cell 102, photovoltaic cell 102 will produce a maximum DC output power. When incident angle 114 is an angle other than 90 degrees (i.e., greater than or less than 90 degrees), photovoltaic cell 102 will produce less than the maximum DC output power. In one embodiment, when a plurality of photovoltaic cells 102 are connected to form an array, the DC output power of each of photovoltaic cells 102 of the array is combined to provide a total DC output power.

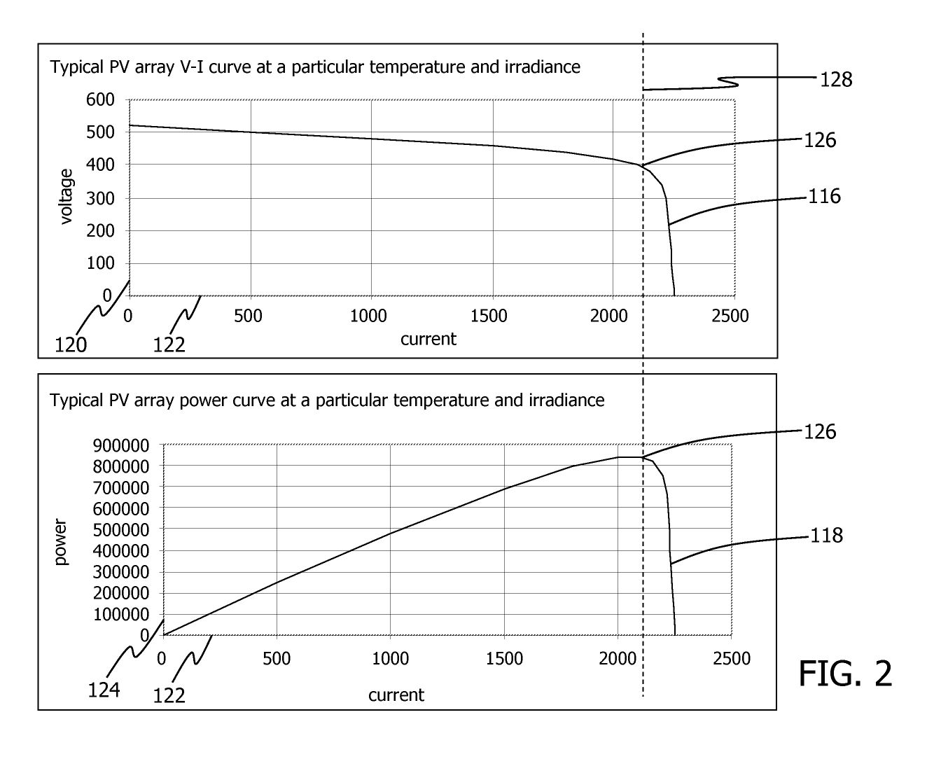

FIG. 2 shows an exemplary plot of a (voltage-current) V-I curve 116 and a power curve 118 of a photovoltaic cell 102. V-I curve 116 plots a photovoltaic array DC voltage 120 and a photovoltaic array DC current 122. Power curve 118 plots power output 124 to the photovoltaic array DC current 122. A maximum power operating point 126 is determined by identifying a maximum power on power curve 118, identified generally at point 126 (located along vertical line 128), and the corresponding voltage and current values from V-I curve 116.

As shown in FIG. 2, photovoltaic cell 102 (or photovoltaic array) produces a maximum power 126. When photovoltaic cell 102 operates at a value less than maximum power 126, one of the voltage or current is higher than at the maximum power point. For example, when photovoltaic cell 102 operates at a reduced power to a left side of maximum power point 126, the voltage is higher and the current is lower than at the maximum power point 126. As another example, when photovoltaic cell 102 operates at a reduced power to a right side of maximum power point 126, the current is higher and the voltage is lower than at the maximum power point 126.

The DC output power of photovoltaic cell 102 (or total DC output power of the photovoltaic array) is supplied to power converter 104 as an input power. Power converter 104 may be a DC-DC power converter, a DC-AC power converter, also known as a power inverter, a single-stage power converter, a two-stage power converter, a three stage power converter, or any suitable number of stages for converting the input power to a desired output power.

Power converter 104 has a threshold input power (e.g., a maximum input power) rating. The threshold input power may be, for example, a maximum input power that allows power converter 104 to properly function without overheating, damage to or tripping of a circuit breaker. The threshold input power of converter 104 may be lower than, equal to, or greater than the DC output power of photovoltaic cell 102 (or total DC output power of the photovoltaic array).

In one embodiment where power converter 104 has a threshold input power rating equal to or greater than the DC output power of photovoltaic cell 102, power converter 104 is configured to operate at maximum power operating point 126 in order to produce as much power as photovoltaic array 12 is able to produce for given conditions (i.e., given temperature and irradiance values).

In another embodiment, a power converter 104 is implemented that has a threshold input power rating lower than the DC output power of the photovoltaic cell 102, for example, to reduce cost or to improve reliability. In such cases, if photovoltaic cell 102 is operated at the maximum power level, power converter 104 may be at risk of overheating and/or failure. Thus, it may not be desirable to operate photovoltaic cell 102 at maximum output power.

One method of adjusting an output power of photovoltaic cell 102 is to adjust an angle of the photovoltaic cell 102. For example, controller 106 controls photovoltaic cell 102 to rotate/pivot to a position in which incident angle 114 of incident light 108 is at an angle greater than or less than 90 degrees (FIG. 4). In one embodiment, the controller 106 sends a signal to a pivoting mechanism 130 to pivot photovoltaic cell 102 in a direction such that incident angle 114 of incident light 108 is not 90 degrees. In another embodiment, pivoting mechanism 130 may include a two dimensional or three dimensional pivoting capability.

In one embodiment, wherein a photovoltaic array comprising a plurality of photovoltaic cells 102 is provided, controller 106 may control each photovoltaic cell 102 of the photovoltaic array to all have a same incident angle 114 with respect to incident light 108. In other embodiments, controller 106 may individually control each photovoltaic cell 102 of the photovoltaic array, such that at least two of photovoltaic cells 102 of the photovoltaic array have different incident angles 114. In still other embodiments, controller 106 may control each photovoltaic cell 102 of the photovoltaic array such that one or more photovoltaic cells 102 are at an incident angle of 90 degrees and other photovoltaic cells 102 of the photovoltaic array are at incident angles 114 greater than or less than 90 degrees.

By adjusting photovoltaic cells 102 to have an incident angle 114 greater than or less than 90 degrees, the DC power output of photovoltaic cells 102 may be reduced from a maximum DC power output level.

In instances where light source 110 may move, for example when light source 110 is the Sun, incident angle 114 may continuously change if photovoltaic cell 102 is not pivoted. Controller 106, in one embodiment, is configured to continuously monitor incident angle 114, and adjust/pivot photovoltaic cells 102 to a desired incident angle 114, incrementally, continuously or in real time. The term “real time” is used herein to denote, for example, a near simultaneous action.

In one embodiment, tracking device 112, as described above, determines the incident angle 114 of the photovoltaic cells 102. In other embodiments, tracking device 112 sends a signal to controller 106 indicating incident angle 114 of one or more of photovoltaic cells 102. In still other embodiments, controller 106 is configured to adjust photovoltaic cells 102 to have an incident angle based upon the signal received from tracking device 112.

In one embodiment, controller 106 is configured to monitor the DC output power, voltage and/or current of photovoltaic cells 102. Controller 106 controls the angle of photovoltaic cells 102 to have an incident angle 114 such that the DC output power, voltage and/or current is maintained at a desired level. For example, controller 106, in some embodiments, controls photovoltaic cells 102 to have an incident angle 114 such that the DC output power, voltage and/or current does not exceed a predetermined value, such as the threshold input power of controller 106.

The embodiments described herein are not limited to any particular system controller or processor for performing the processing tasks described herein. The term controller or processor, as used herein, is intended to denote any machine capable of performing the calculations, or computations, necessary to perform the tasks described herein. The terms controller and processor also are intended to denote any machine that is capable of accepting a structured input and of processing the input in accordance with prescribed rules to produce an output. It should also be noted that the phrase “configured to” as used herein means that the controller/processor is equipped with a combination of hardware and software for performing the tasks of embodiments of the invention, as will be understood by those skilled in the art. The term controller/processor, as used herein, refers to central processing units, microprocessors, microcontrollers, reduced instruction set circuits (RISC), application specific integrated circuits (ASIC), logic circuits, and any other circuit or processor capable of executing the functions described herein.

The embodiments described herein embrace one or more computer readable media, including non-transitory computer readable storage media, wherein each medium may be configured to include or includes thereon data or computer executable instructions for manipulating data. The computer executable instructions include data structures, objects, programs, routines, or other program modules that may be accessed by a processing system, such as one associated with a general-purpose computer capable of performing various different functions or one associated with a special-purpose computer capable of performing a limited number of functions. Aspects of the disclosure transform a general-purpose computer into a special-purpose computing device when configured to execute the instructions described herein. Computer executable instructions cause the processing system to perform a particular function or group of functions and are examples of program code means for implementing steps for methods disclosed herein. Furthermore, a particular sequence of the executable instructions provides an example of corresponding acts that may be used to implement such steps. Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), or any other device or component that is capable of providing data or executable instructions that may be accessed by a processing system.

A computer or computing device such as described herein has one or more processors or processing units, system memory, and some form of computer readable media. By way of example and not limitation, computer readable media comprise computer storage media and communication media. Computer storage media include volatile and nonvolatile, removable and non-removable media implemented in any method or technology for storage of information such as computer readable instructions, data structures, program modules or other data. Communication media typically embody computer readable instructions, data structures, program modules, or other data in a modulated data signal such as a carrier wave or other transport mechanism and include any information delivery media. Combinations of any of the above are also included within the scope of computer readable media.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A photovoltaic power system, comprising:
one or more photovoltaic cells that supplies an output power;
a controller that controls an angle of said one or more photovoltaic cells with respect to an incident light; and
a power converter that converts the output power of said photovoltaic cells to converted output power, said power converter having a threshold input power;
wherein said controller is configured to control the angle of said one or more photovoltaic cells with respect to the incident light such that a total output power of said photovoltaic cells is at or below the threshold input power of said power converter.

2. The photovoltaic power system according to claim 1, further comprising a plurality of said photovoltaic cells, wherein said controller is configured to control said plurality of photovoltaic cells to all have a same angle with respect to the incident light.

3. The photovoltaic power system according to claim 1, further comprising a plurality of said photovoltaic cells, wherein said controller individually controls the angle of each photovoltaic cell of said plurality of photovoltaic cells with respect to the incident light.

4. The photovoltaic power system according to claim 3, wherein said controller is configured to control at least two of said plurality of photovoltaic cells to have a different angle with respect to the incident light.

5. The photovoltaic power system according to claim 4, wherein said controller is configured to control the angle of at least one of said plurality of cells to operate at a maximum output level.

6. The photovoltaic power system according to claim 1, further comprising a tracking device configured to determine the angle of said one or more photovoltaic cells with respect to the incident light.

7. The photovoltaic power system according to claim 1, wherein the threshold input power of said power converter is lower than a peak output power of said one or more photovoltaic cells.

8. The photovoltaic power system according to claim 1, wherein said one or more photovoltaic cells are solar cells.

9. The photovoltaic power system according to claim 1, wherein said controller is configured to control the angle of said one or more photovoltaic cells with respect to the incident light to be less than 90 degrees.

10. The photovoltaic power system according to claim 1, wherein said controller is configured to control the angle of said one or more photovoltaic cells with respect to the incident light to achieve a predetermined current and/or voltage.

11. A method of adjusting the power output of a photovoltaic power system, comprising:
determining an output power of one or more photovoltaic (PV) cells of the system; and
controlling an angle of said one or more photovoltaic cells with respect to an incident light such that a total output power of said photovoltaic cells is at or below a threshold input power of a power converter of the system.

12. The method according to claim 11, wherein the system comprises a plurality of said photovoltaic cells, and controlling an angle of said one or more photovoltaic cells comprises controlling said plurality of photovoltaic cells to have a same angle with respect to the incident light.

13. The method according to claim 11, wherein the system comprises a plurality of said photovoltaic cells, and controlling an angle of said one or more photovoltaic cells comprises individually controlling said plurality of photovoltaic cells to have a same angle with respect to the incident light.

14. The method according to claim 13, wherein at least two of said plurality of photovoltaic cells are controlled to have a different angle with respect to the incident light.

15. The method according to claim 14, wherein at least one of said plurality of cells is controlled to operate at a maximum output level.

16. The method according to claim 11, further comprising tracking the angle of said one or more photovoltaic cells with respect to the incident light.

17. The method according to claim 11, wherein the threshold input power of said power converter is lower than a peak output power of said one or more photovoltaic cells.

18. The method according to claim 11, wherein said one or more photovoltaic cells are solar cells.

19. The method according to claim 11, wherein said controlling an angle of said one or more photovoltaic cells comprises controlling the angle of said one or more photovoltaic cells with respect to the incident light to achieve a predetermined current and/or voltage.

20. A computer readable storage medium storing a non-transitory computer program for a method of adjusting the power output of a photovoltaic power system, the method comprising:
determining an output power of one or more photovoltaic cells of the system; and
controlling an angle of said one or more photovoltaic cells with respect to an incident light such that a total output power of said photovoltaic cells is at or below a threshold input power of a power converter of the system.
